(19) United States
(12) Patent Application Publication
(10) Pub. No.: US 2025/0357326 A1
(43) Pub. Date: Nov. 20, 2025

(54) SEMICONDUCTOR DIE HAVING A METALLIZATION LAYER INCLUDING A METAL LAYER AND A RESISTIVE METAL IN THE METAL LAYER TO DECREASE PARASITIC CAPACITANCE

(71) Applicant: QUALCOMM Incorporated, San Diego, CA (US)

(72) Inventors: Junjing Bao, San Diego, CA (US); John Jianhong Zhu, San Diego, CA (US); Abhishek Jain, San Diego, CA (US); Giridhar Nallapati, San Diego, CA (US)

(21) Appl. No.: 18/665,944

(22) Filed: May 16, 2024

(51) Int. Cl. H01L 23/522; H01L 21/768

(52) U.S. Cl. CPC H01L 23/5228; H01L 21/76829; H01L 23/5226

(57) ABSTRACT

Aspects disclosed in the detailed description include a semiconductor die having a metallization layer including a metal layer and a resistive metal in the metal layer to decrease parasitic capacitance in the metallization layer. Related apparatus and methods are also disclosed. In this regard, in some exemplary aspects disclosed herein, the semiconductor die is provided comprising a metallization layer wherein the metallization layer comprises a dielectric layer having a via and a metal layer adjacent to the dielectric layer. The metal layer comprises a resistive metal coupled to the via. The resistive metal acts as a resistor element in an electronic circuit. Utilizing resistive metal in the metal layer advantageously decreases parasitic capacitance in the metallization layer, and, more specifically, in the dielectric layer resulting from conventional processes which deploy resistive material in the dielectric layer.

### TECHNICAL FIELD

The technology of the disclosure relates to fabricating a resistor in a semiconductor die.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes an outer metallization layer that includes metal interconnects coupled to external metal interconnects (e.g., ball grid array (BGA) interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB.

The die(s) also includes one or more metallization layers that include a metal layer also referred to as a trench layer. Metal interconnects (e.g., metal traces, metal lines) are formed in the metal layer. One or more metallization layers include a dielectric layer, also referred to as a via layer, which includes one or more vias which couple one or more metal interconnects in one metallization layer with one or more metal interconnects in an adjacent metallization layer. The one or more metallization layers are fabricated in the die(s) utilizing a back end of line (BEOL) process. An outer metallization layer of the one or more metallization layers includes metal interconnects fabricated during the BEOL process (e.g., pads). The die(s) also includes die interconnects (e.g., balls or pillars) which are supported by metal pads in the outer metallization layer and electrically couple the metal interconnects in the die(s) to the metal interconnects exposed in the outer metallization layer (e.g., pads) of the package substrate or another die. Resistors are formed with resistive material in one or more via layers and are used, for example, to specifically match impedance of a corresponding analog circuit.

### SUMMARY OF THE DISCLOSURE

Aspects disclosed in the detailed description include a semiconductor die having a metallization layer including a metal layer and a resistive metal in the metal layer to decrease parasitic capacitance in the metallization layer. Related apparatus and methods are also disclosed. In this regard, in some exemplary aspects disclosed herein, the semiconductor die is provided comprising a metallization layer wherein the metallization layer comprises a dielectric layer having a via and a metal layer adjacent to the dielectric layer. The metal layer comprises a resistive metal coupled to the via. The resistive metal acts as a resistor element in an electronic circuit. Utilizing resistive metal in the metal layer advantageously decreases parasitic capacitance in the metallization layer, and, more specifically, in the dielectric layer resulting from conventional processes which deploy resistive material in the dielectric layer.

In an aspect, a semiconductor die is provided. The semiconductor die comprises a metallization layer extending in a first direction. The metallization layer comprises a first dielectric layer comprising a first via extending in a second direction and a metal layer adjacent to the first dielectric layer. The metal layer comprises a resistive metal coupled to the first via.

In another aspect, a method of fabricating a metallization layer in a semiconductor die, the metallization layer extending in a first direction. The method comprises fabricating a first dielectric layer comprising a first via extending in a second direction, fabricating a metal layer adjacent to the first dielectric layer, comprising a resistive metal, and coupling the resistive metal to the first via.

### BRIEF DESCRIPTION OF THE FIGURES

FIG. 1 is a side view of an integrated circuit (IC) that includes a portion of a die, the die including a metallization layer having a dielectric layer and a metal layer wherein the metal layer includes a resistive metal coupled to a via in the dielectric layer to decrease parasitic capacitance in the dielectric layer;

FIG. 2 is a close-up view of a portion of an exemplary metallization layer having a dielectric layer and a metal layer wherein the metal layer includes a resistive metal coupled to a via in the dielectric layer to decrease parasitic capacitance in the dielectric layer;

FIGS. 3A-3C show three exemplary stages for coupling a via in a via layer of a metallization layer to a resistive metal in the metal layer of the metallization layer of FIG. 2;

FIG. 3A shows a first etching stage for coupling the via in the via layer of the metallization layer to the resistive metal in the metal layer of the metallization layer of FIG. 2;

FIG. 3B shows a second etching stage for coupling the via in the via layer of the metallization layer to the resistive metal in the metal layer of the metallization layer of FIG. 2;

FIG. 3C shows a depositing metal stage for coupling the via in the via layer of the metallization layer to the resistive metal in the metal layer of the metallization layer of FIG. 2;

FIGS. 4A-4D show four exemplary stages for coupling a via in a via layer of a metallization layer to a resistive metal in the via layer of the metallization layer;

FIG. 4A shows a first etching stage for coupling the via in the via layer of the metallization layer to the resistive metal in the via layer of the metallization layer;

FIG. 4B shows a second etching stage for coupling the via in the via layer of the metallization layer to the resistive metal in the via layer of the metallization layer;

FIG. 4C shows a third etching stage for coupling the via in the via layer of the metallization layer to the resistive metal in the via layer of the metallization layer;

FIG. 4D shows a metal depositing stage for coupling the via in the via layer of the metallization layer to the resistive metal in the via layer of the metallization layer;

FIG. 5 is a flowchart illustrating an exemplary fabrication process for fabricating a metallization layer having a dielectric layer and a metal layer wherein the metal layer includes a resistive metal coupled to a via in the dielectric layer to decrease parasitic capacitance in the dielectric layer in FIG. 2;

FIGS. 6A-6F is a flowchart of illustrating another exemplary fabrication process for fabricating a metallization layer having a dielectric layer and a metal layer wherein the metal layer includes a resistive metal coupled to a via in the dielectric layer to decrease parasitic capacitance in the dielectric layer, including, but not limited to, the metallization layer in FIG. 2;

FIGS. 7A-7I are exemplary fabrication stages during fabrication of the metallization layer according to the fabrication process in FIGS. 6A-6F;

FIG. 8 is a block diagram of an exemplary wireless communications device that includes radio-frequency (RF) components deployed in an IC package, wherein the IC package includes a semiconductor die having a metallization layer, including, but not limited to, the metallization layer in FIG. 2 and fabricated according to the exemplary fabrication processes in FIGS. 5 and 6A-6F; and

FIG. 9 is a block diagram of an exemplary processor-based system that can include components deployed in an IC package, wherein the IC package includes a semiconductor die having a metallization layer, including, but not limited to, the metallization layer in FIG. 2 and fabricated according to the exemplary fabrication processes in FIGS. 5, and 6A-6F.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise. The term “directly adjacent” as used herein means adjoining something as shown in the Figures.

Aspects disclosed in the detailed description include a semiconductor die having a metallization layer including a metal layer and a resistive metal in the metal layer to decrease parasitic capacitance in the metallization layer. Related apparatus and methods are also disclosed. In this regard, in some exemplary aspects disclosed herein, the semiconductor die is provided comprising a metallization layer wherein the metallization layer comprises a dielectric layer having a via and a metal layer adjacent to the dielectric layer. The metal layer comprises a resistive metal coupled to the via. The resistive metal acts as a resistor element in an electronic circuit. Utilizing resistive metal in the metal layer advantageously decreases parasitic capacitance in the metallization layer, and, more specifically, in the dielectric layer resulting from conventional processes which deploy resistive material in the dielectric layer.

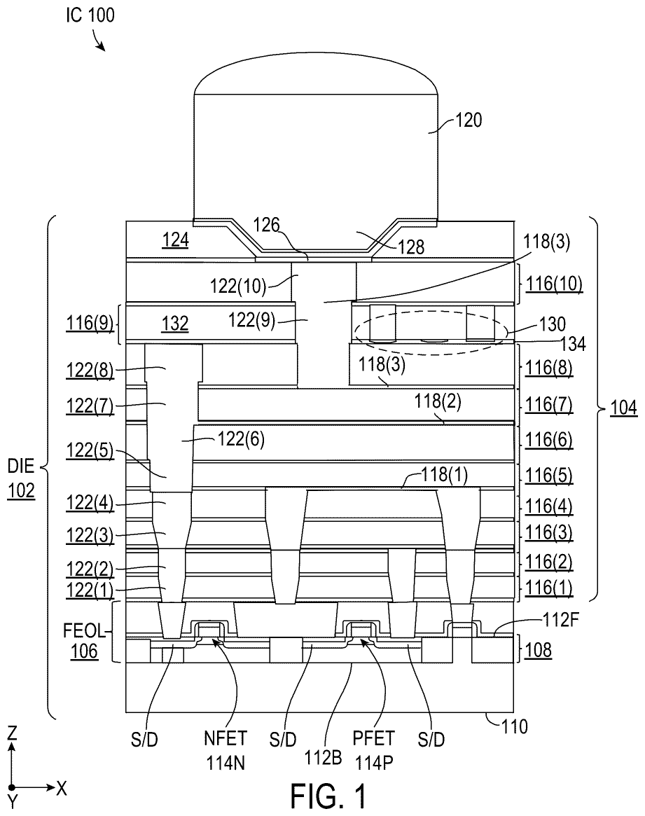

FIG. 1 is a side view of an integrated circuit (IC) 100 that includes a portion of a die, the die including a metallization layer having a dielectric layer and a metal layer wherein the metal layer includes a resistive metal coupled to a via in the dielectric layer to decrease parasitic capacitance in the dielectric layer. A die 102 includes a back end of line (BEOL) interconnect structure 104 formed by a BEOL process and disposed on a front-end-of-line (FEOL) structure 106. The FEOL structure 106 includes an active, semiconductor layer 108 that is formed on a substrate 110. The semiconductor layer 108 extends in a first, horizontal direction, which is the X-axis and Y-axis directions as shown in FIG. 1. The semiconductor layer 108 has a first, front side 112F and a second, back side 112B opposite the first, front side 112F in a second, vertical direction (Z-axis direction). P-type field-effect transistors (FETs) (PFETs) and N-type FETs (NFETs) 114P, 114N are formed in the semiconductor layer 108. The BEOL interconnect structure 104, as a front side interconnect structure 104, is disposed adjacent to the front side 112F of the semiconductor layer 108 in the second, vertical direction (Z-axis direction). The BEOL interconnect structure 104 facilitates signal routing in the die 102 on the front side 112F of the semiconductor layer 108. In this regard, the BEOL interconnect structure 104 includes a plurality of front side, metallization layers 116(1)-116(10) that each include one or more metal interconnects, such as metal interconnects 118(1)-118(3) that can provide direct or indirect interconnections between the FETs 114P, 114N and die interconnects 120 (e.g., a solder bump) adjacent to an upper metallization layer 116(10) of the BEOL interconnect structure 104. The metal interconnects 118(1)-118(3) extend in the first, horizontal direction(s) (X- and/or Y-axis directions). The BEOL interconnect structure 104 also includes via layers 122(1)-122(10) disposed through the front side metallization layers 116(1)-116(10) to provide interconnects between metal interconnects 118(1)-118(3) in adjacent metallization layers 116(4)-116(5), 116(6)-116(7), and 116(9)-116(10), respectively. A first passivation layer 124 extends in the first, horizontal direction adjacent to the outer metallization layer 116(10). A metal pad 126 is disposed between the passivation layer 124 and the outer metallization layer 116(10) to mechanically support the die interconnect 120. The die interconnect 120 couples to the metal pad 126 through a via 128. The metal pad 126 couples to metal interconnect 118(3) through via layer 122(10).

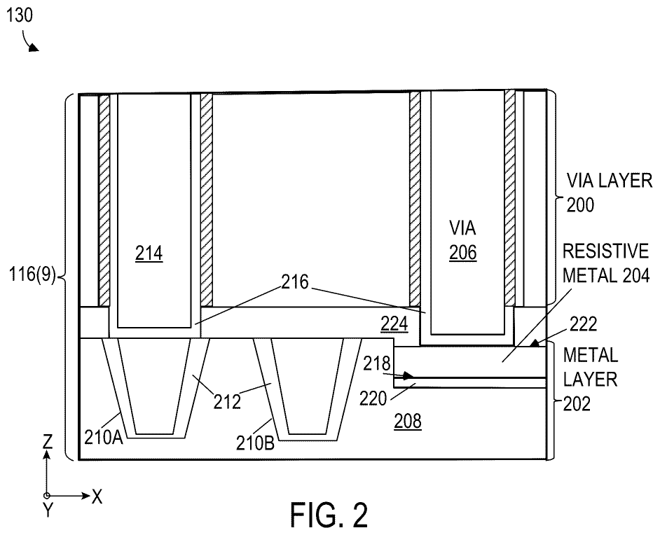

With continuing reference to FIG. 1, a portion 130 of metallization layer 116(9) having a dielectric layer 132 and a metal layer 134 wherein the metal layer 134 includes a resistive metal coupled to a via in the dielectric layer 132 to decrease parasitic capacitance in the dielectric layer 132 and will be discussed in more detail in FIG. 2. Although the portion 130 of the metallization layer 116(9) includes a resistive metal, resistive metal may be deployed in any of the other metallization layers 116(1)-116(8) and 116(10).

FIG. 2 is a close-up view of a portion of an exemplary metallization layer, such as the portion 130 of the metallization layer 116(9) in FIG. 1, having a dielectric layer 200, also referred to as via layer 200, and a metal layer 202 wherein the metal layer 202 includes a resistive metal 204 coupled to a via 206 in the dielectric layer 200 to decrease parasitic capacitance in the dielectric layer 200. The dielectric layer 200 has a dielectric constant, K, between 2.4 and 2.6. The metallization layer 116(9) extends in a first, horizontal direction (X- , Y-axes direction). The dielectric layer 200 includes the via 206 extending in a second, vertical direction (Z-axis direction). The metal layer 202 extends in the first, horizontal direction and is adjacent to the dielectric layer 200. The metal layer 202 includes the resistive metal 204 which is coupled to the via 206.

The metal layer 202 also includes a dielectric layer 208 and metal interconnects 210A, 210B. The metal interconnects 210A, 210B include metal barrier layers 212. The dielectric layer 200 also includes a via 214 coupled to the metal interconnect 210A. The vias 206 and 214 include barrier layers 216.

The resistive metal 204 has a first, bottom surface 218. The metal layer 202 also includes a first etch stop layer 220 between the bottom surface 218 of the resistive metal 204 and the dielectric layer 208. The resistive metal 204 has a second, top surface 222. The metallization layer 116(9) also includes a second etch stop layer 224 between the top surface 222 of the resistive metal 204 and the dielectric layer 200. The etch stop layers 220, 224 are preferably silicon carbon nitride (SiCN). The resistive metal 204 is preferably titanium nitride (TiN).

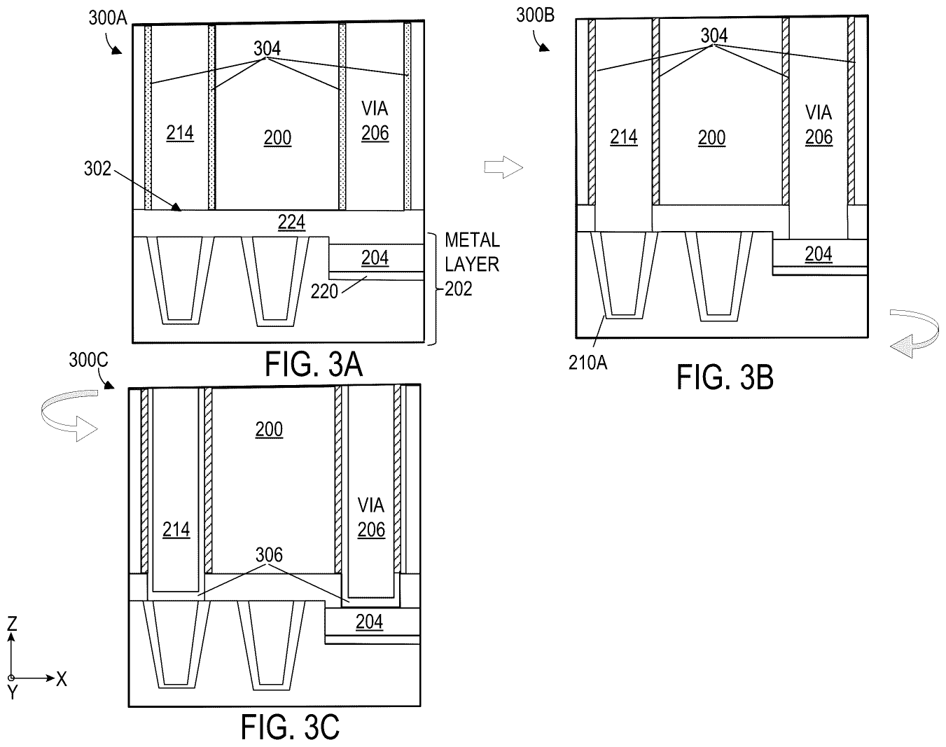

FIGS. 3A-3C show three exemplary stages 300A-300C for coupling a via in a via layer of a metallization layer to a resistive metal in the metal layer of the metallization layer of FIG. 2. FIG. 3A shows a first stage 300A for coupling the via in the via layer of the metallization layer to the resistive metal in the metal layer of the metallization layer of FIG. 2. In particular, the first stage 300A includes dry etching through the dielectric layer 200. Both the via 214 and the via 206 advantageously have the same depth and terminate at this stage at a top surface 302 of the second etch stop layer 224. The second etch stop layer 224 stops the dry etching process to prevent over etching from the dry etching process into the metal interconnect 210A and resistive metal 204. As a result of this first etching stage, vertical edges 304 of the dielectric layer 200 that border the vias 206, 214 are degraded slightly increasing the overall dielectric constant, K, of the dielectric layer 200.

FIG. 3B shows a second stage 300B for coupling the via in the via layer of the metallization layer to the resistive metal in the metal layer of the metallization layer of FIG. 2. In particular, the second stage 300B includes dry etching the via 214 through the second etch stop layer 224 to the metal interconnect 210A and dry etching the via 206 through the second etch stop layer 224 to the resistive metal 204. As a result of this second etching stage 300B, the vertical edges 304 of the dielectric layer 200 that border the vias 206, 214 are further degraded slightly increasing the overall dielectric constant, K, of the dielectric layer 200. The higher the K value the more parasitic capacitance is stored in dielectric layer 200 due to surrounding metal such as the metal interconnects 210A, 210B and the vias 206, 214.

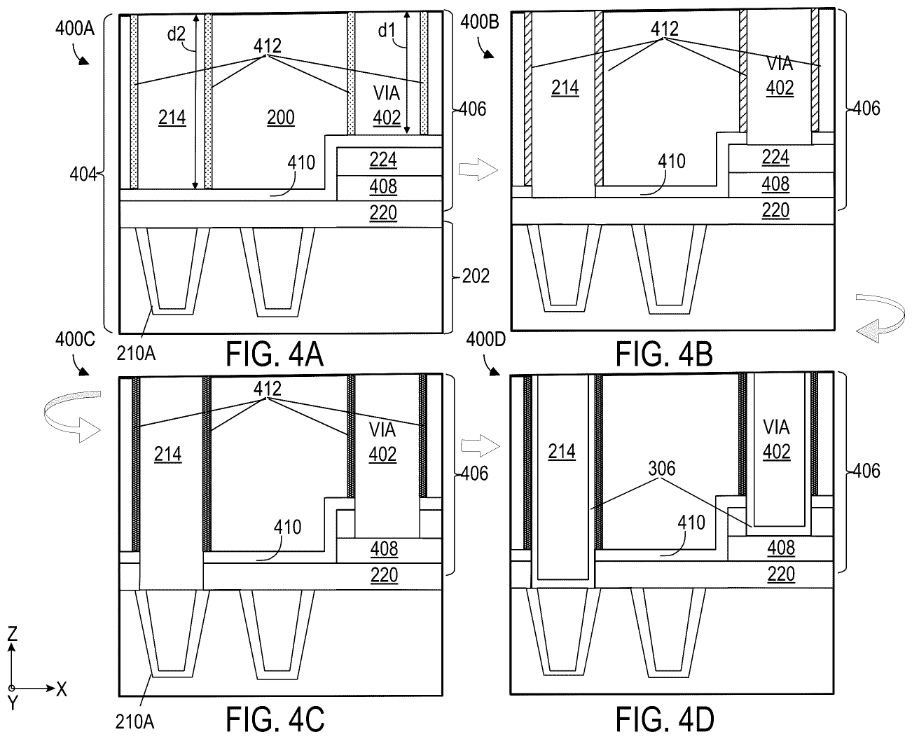

FIG. 3C shows a metal depositing stage 300C for coupling the via in the via layer of the metallization layer to the resistive metal in the metal layer of the metallization layer of FIG. 2. In particular, the third stage 300C includes depositing a barrier layer 306 and depositing metal in the vias 206, 214. The overall parasitic capacitance of the dielectric layer 200 is less than the conventional process for incorporating a resistive metal in a metallization layer because the conventional process, as will be described in FIGS. 4A-4D, requires aluminum oxide (AlO) which has a high dielectric constant and utilizes an additional etching step to etch away only a portion of the AlO whereby the additional etching stop further damages the vertical edges of the dielectric layer and thus further increasing the dielectric constant of the via layer along with the remaining portion of AlO.

FIGS. 4A-4D show four exemplary stages 400A-400D for coupling a via 402 in a via layer 406 of a metallization layer 404 to a resistive metal 408 in the via layer 406 of the metallization layer 404. Common elements between the metallization layer 404 in FIGS. 4A-4D and the metallization layer 116(9) in FIGS. 2 and 3A-3C are shown with common element numbers. FIG. 4A shows a first etching stage 400A for coupling the via 402 in the via layer 406 of the metallization layer 404 to the resistive metal 408 in the via layer 406 of the metallization layer 404. In particular, stage 400A includes dry etching through the dielectric layer 200 to an etch stop layer 410. The etch stop layer 410 is composed of aluminum oxide (AlO) and has a high dielectric constant, K, between 3-9 depending on the level of impurity of the AlO material and contributes to the overall dielectric constant of the via layer 406. Additionally, as a result of the etching stage 400A, vertical edges 412 of the via layer 406 that border the vias 402, 214 are degraded slightly increasing the overall dielectric constant, K, of the via layer 406.

Unlike the resistive metal 408, the resistive metal 204 of FIGS. 2 and 3A-3C is in the metal layer 202. Since the resistive metal 408 is in the via layer 406, the depths, d1, d2 of the via 402 and via 214, respectively, are different. Since the depths are different, the additional etch stop layer 410 is a strong etch stop layer (e.g., AlO) that allows continued exposure to dry etching in order to create a deeper depth, d2, for the via 214 while stopping the etching at depth, d1, in the via 402 during the same etching stage 400A. Without the strong etch stop layer 410, the second etch stop layer 224 would be over etched into resistive metal 408 while etching through the dielectric layer 200 to form the via 214.

FIG. 4B shows a second etching stage 400B for coupling the via 402 in the via layer 406 of the metallization layer 404 to the resistive metal 408 in the via layer 406 of the metallization layer 404. In particular, stage 400B includes wet etching through the etch stop layer 410 to expose the second etch stop layer 224 at the bottom of the via 402 and to expose the portion of the first etch stop layer 220 at the bottom of the via 214. As a result of this second etching stage 400B, the vertical edges 412 of the via layer 406 that border the vias 402, 214 are further degraded increasing the overall dielectric constant, K, of the via layer 406.

FIG. 4C shows a third etching stage 400C for coupling the via 402 in the via layer 406 of the metallization layer 404 to the resistive metal 408 in the via layer 406 of the metallization layer 404. In particular, stage 400C includes wet etching through the second etch stop layer 224 to expose the resistive metal 408 at the bottom of the via 402 and, through the portion of the first etch stop layer 220 at the bottom of the via 214, to expose the metal interconnect 210A. As a result of this third etching stage 400C, the vertical edges 412 of the via layer 406 that border the vias 402, 214 are further degraded slightly increasing the overall dielectric constant, K, of the via layer 406 again.

FIG. 4D shows a metal depositing stage 400D for coupling the via 402 in the via layer 406 of the metallization layer 404 to the resistive metal 408 in the via layer 406 of the metallization layer 404. In particular, the fourth stage 400D includes depositing the barrier layer 306 and depositing metal in the vias 402, 214 to form metal vias 402, 214. The higher the K value the more parasitic capacitance is stored in the via layer 406 due to surrounding metal such as the metal interconnects 210A, 210B and the vias 402, 214. The overall parasitic capacitance of the via layer 406 is greater than the via layer 200 of FIG. 2 due to the remnants of the etch stop layer 410 which has a high dielectric constant and the additional damage to the via layer 406 caused by etching through portions of the etch stop layer 410.

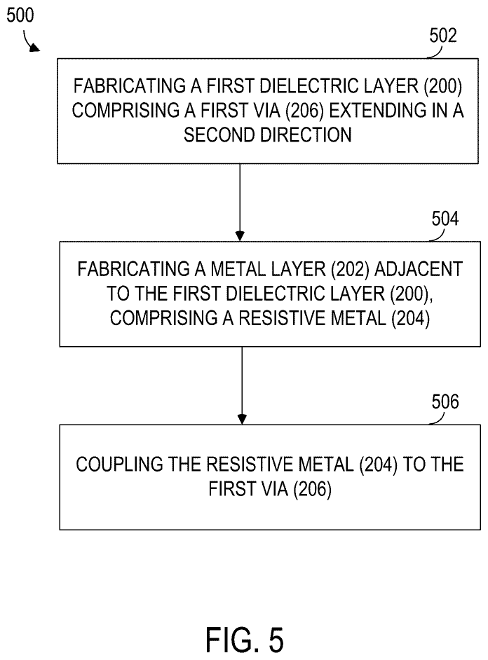

A metallization layer, including, but not limited to, the metallization layer 116 (9) in FIGS. 1-2, having a dielectric layer and a metal layer wherein the metal layer includes a resistive metal coupled to a via in the dielectric layer to decrease parasitic capacitance in the dielectric layer can be fabricated by different fabrication processes. FIG. 5 is a flowchart illustrating an exemplary fabrication process 500 for fabricating a metallization layer, such as the metallization layer 116(9) in FIGS. 1-2, having a dielectric layer and a metal layer wherein the metal layer includes a resistive metal coupled to a via in the dielectric layer to decrease parasitic capacitance in the dielectric layer in FIG. 2.

In this regard, a first exemplary step for fabricating a metallization layer in a semiconductor die wherein the metallization layer extends in a first direction includes fabricating a first dielectric layer 200 comprising a first via 206 extending in a second direction (block 502 in FIG. 5). The next step in the fabrication process 500 can include fabricating a metal layer 202 adjacent to the first dielectric layer 200, comprising a resistive metal 204 (block 504 in FIG. 5). The next step in the fabrication process 500 can include coupling the resistive metal 204 to the first via 206 (block 506 in FIG. 5).

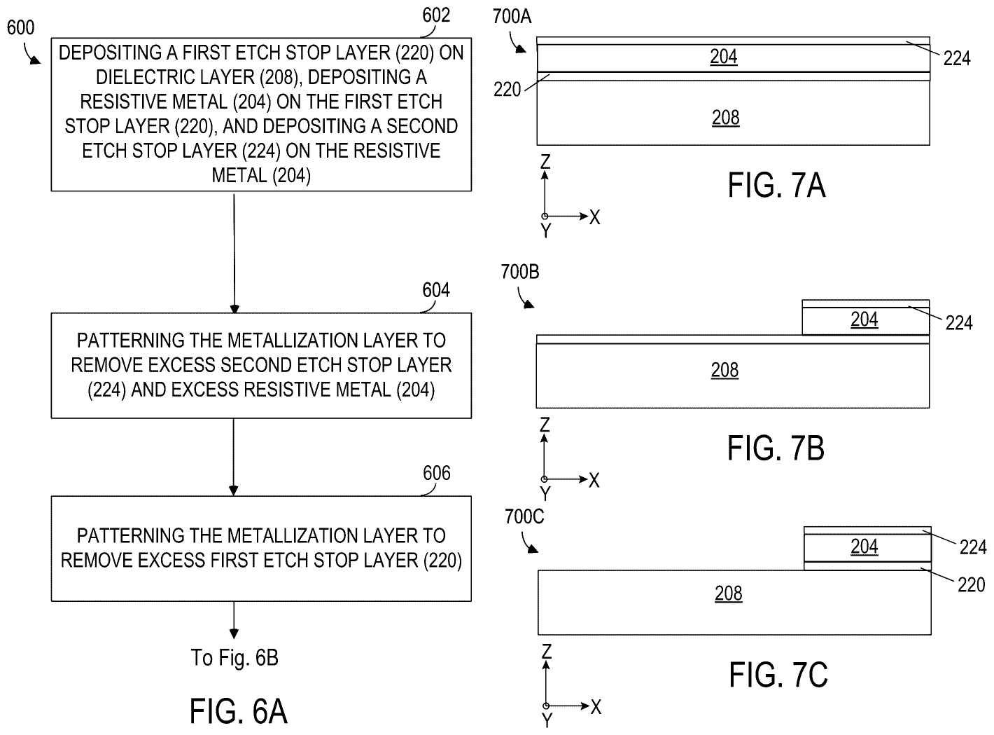

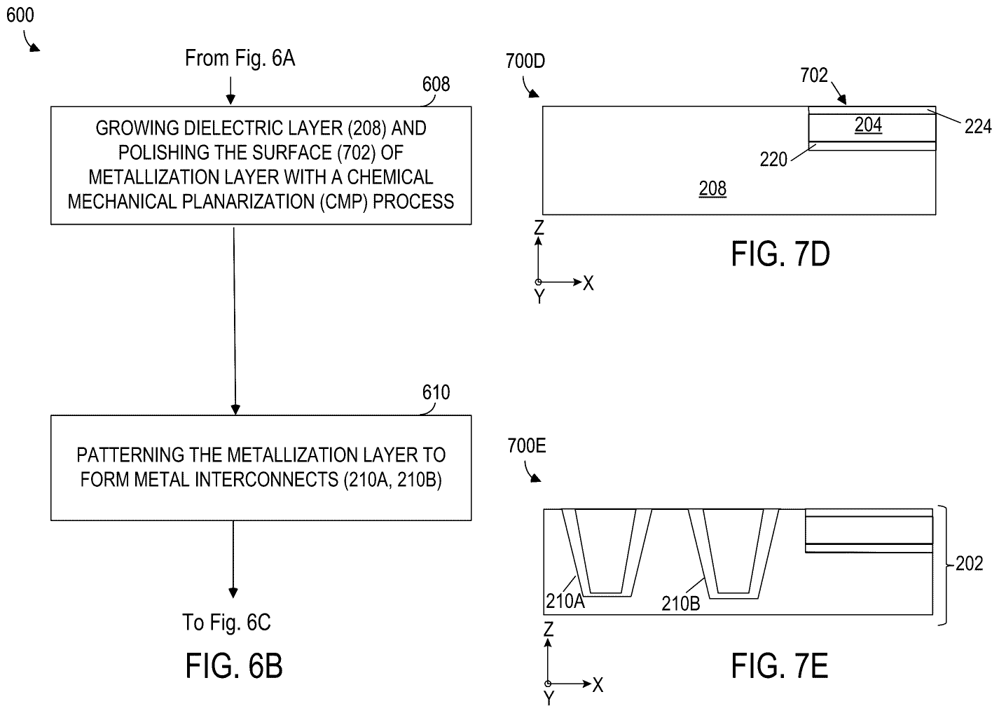

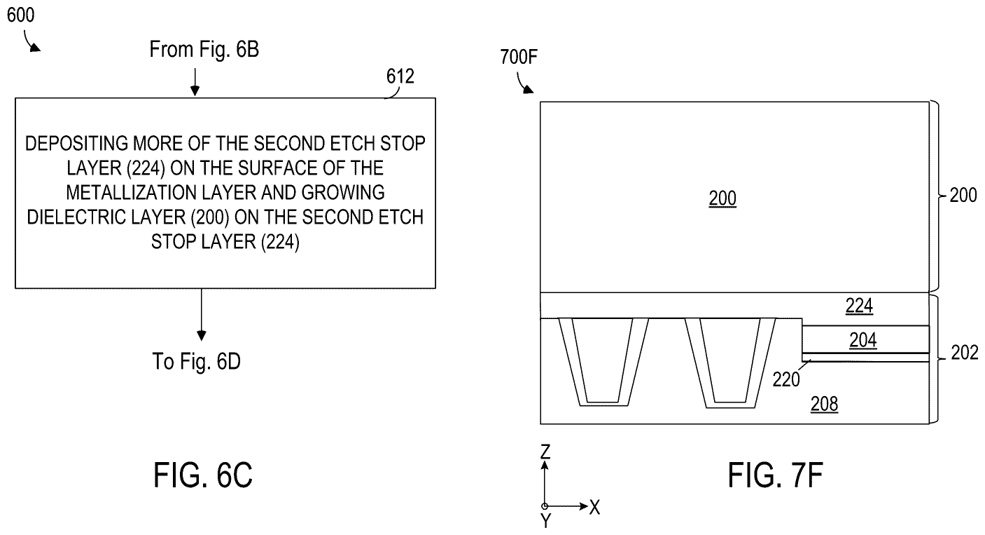

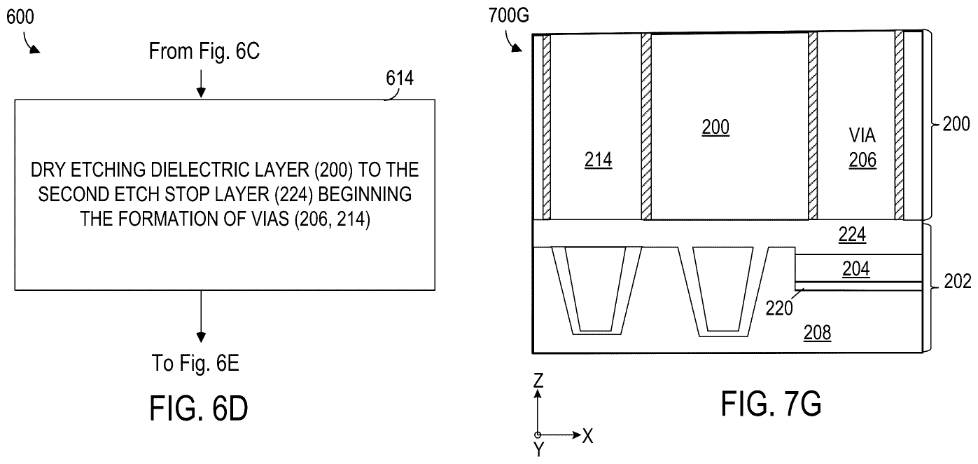

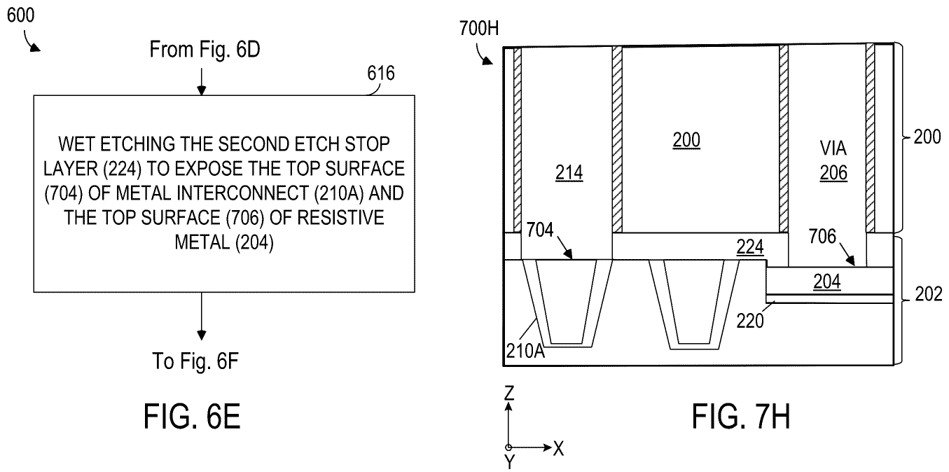

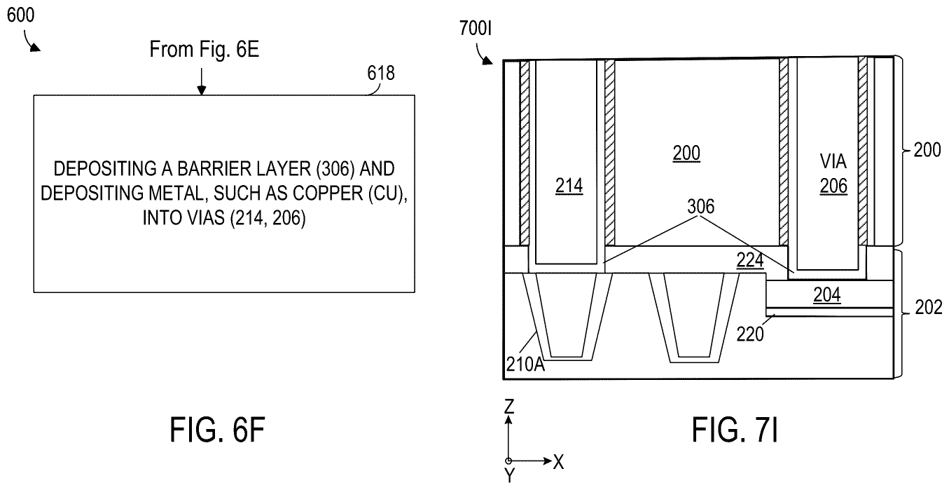

Other fabrication processes can also be employed to fabricate a metallization layer, including, but not limited to, the metallization layer 116(9) in FIGS. 1-2, having a dielectric layer and a metal layer wherein the metal layer includes a resistive metal coupled to a via in the dielectric layer to decrease parasitic capacitance in the dielectric layer. In this regard, FIGS. 6A-6F is a flowchart of illustrating another exemplary fabrication process 600 for fabricating a metallization layer, including, but not limited to, the metallization layer 116(9) in FIGS. 1-2, having a dielectric layer and a metal layer wherein the metal layer includes a resistive metal coupled to a via in the dielectric layer to decrease parasitic capacitance in the dielectric layer. FIGS. 7A-71 are exemplary fabrication stages during fabrication of the metallization layer according to the fabrication process 600 in FIGS. 6A-6F. Blocks 602-610 of the fabrication process 600 describe fabricating a metal layer and will be described in connection with the metal layer 202 of FIG. 2. Blocks 612-618 of the fabrication process 600 describe fabricating a via layer and will be described in connection with the via layer 200.

In this regard, as shown in fabrication stage 700A in FIG. 7A, an exemplary step in the fabrication process 600 is depositing a first etch stop layer 220 on a dielectric layer 208, depositing a resistive metal 204 on the first etch stop layer 220, and depositing a second etch stop layer 224 on the resistive metal 204 (block 602 in FIG. 6A). As shown in fabrication stage 700B in FIG. 7B, a next step in the fabrication process 600 can include patterning the metallization layer to remove excess second etch stop layer 224 and excess resistive metal 204 (block 604 in FIG. 6A). As shown in fabrication stage 700C in FIG. 7C, a next step in the fabrication process 600 can include patterning the metallization layer to remove excess first etch stop layer 220 (block 606 in FIG. 6A).

As shown in fabrication stage 700D in FIG. 7D, a next step in the fabrication process 600 can include growing the dielectric layer 208 and polishing a surface 702 of the metallization layer with a chemical mechanical planarization (CMP) process (block 608 in FIG. 6B). As shown in fabrication stage 700E in FIG. 7E, a next step in the fabrication process 600 can include patterning the metallization layer to form metal interconnects 210A, 210B (block 610 in FIG. 6B). As shown in fabrication stage 700F in FIG. 7F, a next step in the fabrication process 600 can include depositing more of the second etch stop layer 224 on the surface 702 of the metallization layer and growing dielectric layer 200 on the second etch stop layer 224 (block 612 in FIG. 6C). As shown in fabrication stage 700G in FIG. 7G, a next step in the fabrication process 600 can include dry etching the dielectric layer 200 to the second etch stop layer 224 beginning the formation of vias 206, 214 (block 614 in FIG. 6D). As shown in fabrication stage 700H in FIG. 7H, a next step in the fabrication process 600 can include wet etching the second etch stop layer 224 to expose a top surface 704 of the metal interconnect 210A and a top surface 706 of the resistive metal 204 (block 616 in FIG. 6E). As shown in fabrication stage 7001 in FIG. 71, a next step in the fabrication process 600 can include depositing a barrier layer 306 and depositing metal, such as Copper (Cu), into the vias 214 and 206 (block 618 in FIG. 5C).

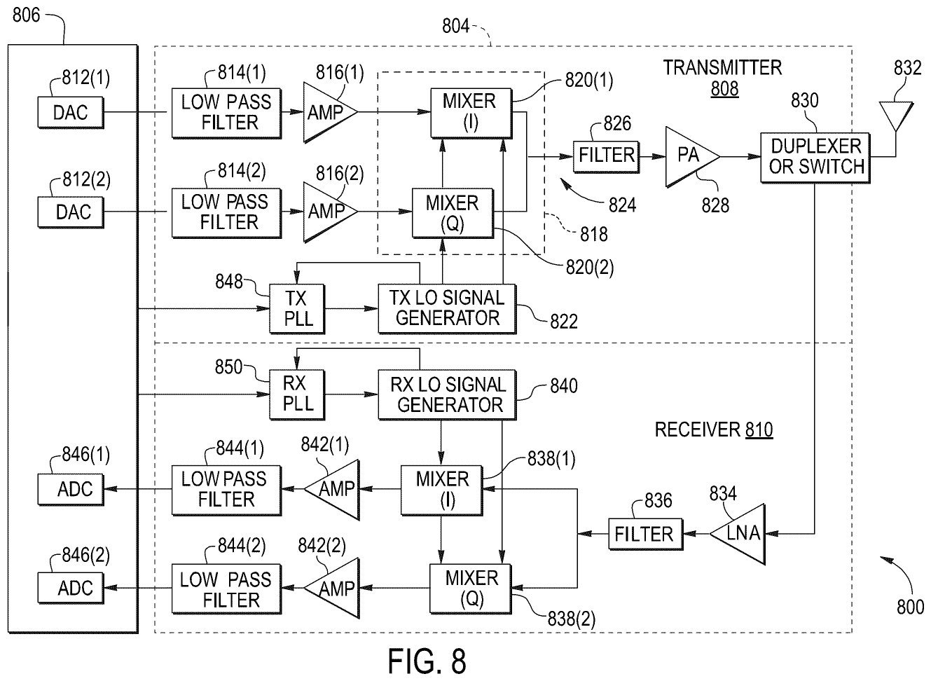

FIG. 8 is a block diagram of an exemplary wireless communications device that includes radio-frequency (RF) components deployed in an IC package, wherein the IC package includes a semiconductor die having a metallization layer, including, but not limited to, the metallization layer in FIG. 2 and according to the exemplary fabrication processes in FIGS. 5, and 6A-6F. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals (e.g., I and Q output currents) for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency up-conversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Down-conversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency up-conversion, while the RX LO signal generator 840 generates the I and Q RX LO signals used for frequency down-conversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

A semiconductor die including a metallization layer having a dielectric layer and a metal layer wherein the metal layer includes a resistive metal coupled to a via in the dielectric layer to decrease parasitic capacitance in the dielectric layer as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

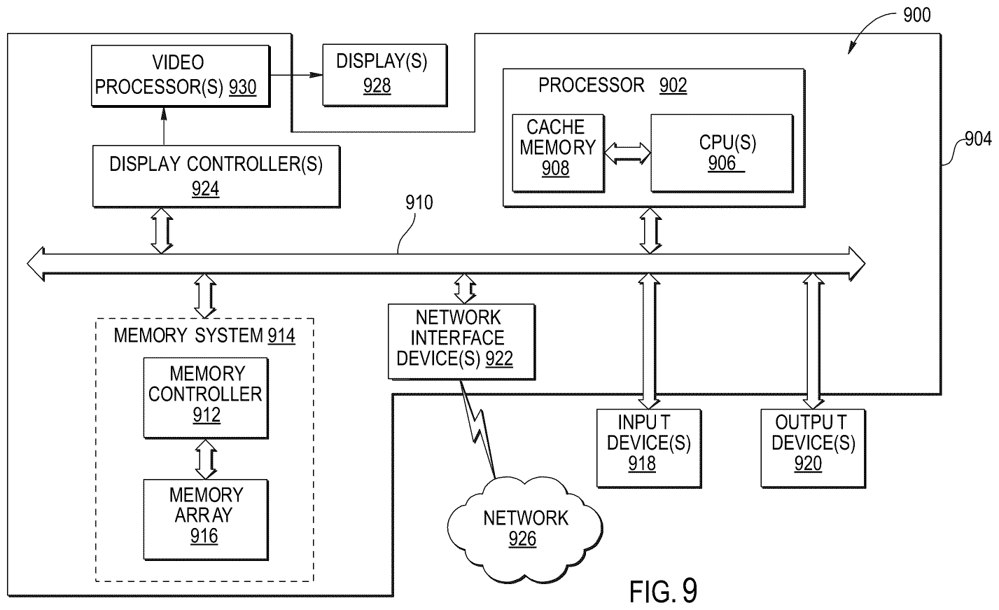

In this regard, FIG. 9 is a block diagram of an exemplary processor-based system 900 that can include components deployed in an IC package, wherein the IC package includes a semiconductor die having a metallization layer, including, but not limited to, the metallization layer in FIG. 2 and according to the exemplary fabrication processes in FIGS. 5, and 6A-6F.

In this example, the processor-based system 900 includes a processor 902 deployed on a semiconductor die 904 including a metallization layer having a dielectric layer and a metal layer wherein the metal layer includes a resistive metal coupled to a via in the dielectric layer as disclosed herein and includes one or more central processing units (captioned as “CPUs” in FIG. 9) 906, which may also be referred to as CPU cores or processor cores. The processor 902 may have eache memory 908 coupled to the processor 902 for rapid access to temporarily stored data. The processor 902 is coupled to a system bus 910 and can intercouple server and client devices included in the processor-based system 900. As is well known, the processor 902 communicates with these other devices by exchanging address, control, and data information over the system bus 910. For example, the processor 902 can communicate bus transaction requests to a memory controller 912, as an example of a client device. Although not illustrated in FIG. 9, multiple system buses 910 could be provided, wherein each system bus 910 constitutes a different fabric.

Other server and client devices can be connected to the system bus 910 and deployed in a die including a metallization layer having a dielectric layer and a metal layer wherein the metal layer includes a resistive metal coupled to a via in the dielectric layer to decrease parasitic capacitance in the dielectric layer. As illustrated in FIG. 9, these devices can include a memory system 914 that includes the memory controller 912 and a memory array(s) 916, one or more input devices 918, one or more output devices 920, one or more network interface devices 922, and one or more display controllers 924, as examples. The input device(s) 918 can include any type of input device, including but not limited to input keys, switches, voice processors, etc. The output device(s) 920 can include any type of output device, including, but not limited to, audio, video, other visual indicators, etc. The network interface device(s) 922 can be any device configured to allow exchange of data to and from a network 926. The network 926 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 922 can be configured to support any type of communications protocol desired.

The processor 902 may also be configured to access the display controller(s) 924 over the system bus 910 to control information sent to one or more displays 928. The display controller(s) 926 sends information to the display(s) 926 to be displayed via one or more video processors 930, which process the information to be displayed into a format suitable for the display(s) 928. The display controller(s) 924 and/or the video processors 930 may comprise or be integrated into a GPU. The display(s) 928 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A semiconductor die, comprising:
a metallization layer extending in a first direction, comprising:
   a first dielectric layer comprising a first via extending in a second direction; and
   a metal layer adjacent to the first dielectric layer, comprising:
      a resistive metal coupled to the first via.
         2. The semiconductor die of clause 1, wherein:
the first dielectric layer further comprises:
   a second via; and
the metal layer further comprises:
   one or more metal interconnects coupled to the second via.
      3. The semiconductor die of clause 1 or 2, wherein:
the resistive metal has a first surface; and
the metal layer comprises:
   a second dielectric layer; and
   a first etch stop layer between the first surface of the resistive metal and the second dielectric layer.
      4. The semiconductor die of clause 3, wherein:
the resistive metal has a second surface; and
the semiconductor die further comprises:
   a second etch stop layer between the second surface of the resistive metal and the first dielectric layer.
      5. The semiconductor die of clause 4, wherein:
the first etch stop layer comprises silicon carbon nitride (SiCN); and
the second etch stop layer comprises SiCN.
   6. The semiconductor die of any of clauses 1-5, wherein the resistive metal comprises titanium nitride (TiN).
   7. The semiconductor die of any of clauses 1-6, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
   8. A method of fabricating a metallization layer in a semiconductor die, the metallization layer extending in a first direction comprising:
fabricating a first dielectric layer comprising a first via extending in a second direction;
fabricating a metal layer adjacent to the first dielectric layer, comprising a resistive metal; and
coupling the resistive metal to the first via.
   9. The method of clause 8, wherein:
fabricating the first dielectric layer further comprises:
   fabricating a second via;
fabricating the metal layer further comprises:
   fabricating a metal interconnect; and
the method further comprises:
   coupling to the second via to the metal interconnect.
      10. The method of clause 8 or 9, wherein:
the resistive metal has a first surface; and
fabricating the metal layer further comprises:
   fabricating a second dielectric layer; and
   fabricating a first etch stop layer between the first surface of the resistive metal and the second dielectric layer.
      11. The method of clause 10, wherein:
the resistive metal has a second surface; and
fabricating the metal layer further comprises:
   fabricating a second etch stop layer between the second surface of the resistive metal and the first dielectric layer.
      12. The method of clause 11, wherein:
the first etch stop layer comprises silicon carbon nitride (SiCN); and
the second etch stop layer comprises SiCN.
   13. The method of any of clauses 8-12, wherein the resistive metal comprises titanium nitride (TiN).
   14. The method of any of clauses 8-13, wherein the metal layer comprises a second dielectric layer, wherein fabricating the metal layer further comprises:
depositing a first etch stop layer adjacent to the second dielectric layer;
depositing the resistive metal adjacent to the first etch stop layer; and
depositing a second etch stop layer adjacent to the resistive metal.
   15. The method of clause 14, wherein fabricating the metal layer further comprises:
patterning the metal layer to remove excess etch stop from the first etch stop layer and excess etch stop from the second etch stop layer whereby the first etch stop layer remains adjacent to a first surface of the resistive metal and the second etch stop layer remains adjacent to a second surface of the resistive metal.
   16. The method of any of clauses 8-15, wherein fabricating the first dielectric layer further comprises:
etching the first dielectric layer to the second etch stop layer to begin formation of the first via.
   17. The method of clause 16, wherein fabricating the first dielectric layer further comprises:
etching the second etch stop layer to expose the second surface of the resistive metal.
   18. The method of clause 17, further comprising:
depositing metal into the first via.

What is claimed is:

1. A semiconductor die, comprising:
a metallization layer extending in a first direction, comprising:
a first dielectric layer comprising a first via extending in a second direction; and
a metal layer adjacent to the first dielectric layer, comprising:
a resistive metal coupled to the first via.

2. The semiconductor die of claim 1, wherein:
the first dielectric layer further comprises:
a second via; and
the metal layer further comprises:
one or more metal interconnects coupled to the second via.

3. The semiconductor die of claim 1, wherein:
the resistive metal has a first surface; and
the metal layer comprises:
a second dielectric layer; and
a first etch stop layer between the first surface of the resistive metal and the second dielectric layer.

4. The semiconductor die of claim 3, wherein:
the resistive metal has a second surface; and
the semiconductor die further comprises:
a second etch stop layer between the second surface of the resistive metal and the first dielectric layer.

5. The semiconductor die of claim 4, wherein:
the first etch stop layer comprises silicon carbon nitride (SiCN); and
the second etch stop layer comprises SiCN.

6. The semiconductor die of claim 4, wherein the resistive metal comprises titanium nitride (TiN).

7. The semiconductor die of claim 1, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

8. A method of fabricating a metallization layer in a semiconductor die, the metallization layer extending in a first direction comprising:
fabricating a first dielectric layer comprising a first via extending in a second direction;
fabricating a metal layer adjacent to the first dielectric layer, comprising a resistive metal; and
coupling the resistive metal to the first via.

9. The method of claim 8, wherein:
fabricating the first dielectric layer further comprises:
fabricating a second via;
fabricating the metal layer further comprises:
fabricating a metal interconnect; and
the method further comprises:
coupling to the second via to the metal interconnect.

10. The method of claim 8, wherein:
the resistive metal has a first surface; and
fabricating the metal layer further comprises:
fabricating a second dielectric layer; and
fabricating a first etch stop layer between the first surface of the resistive metal and the second dielectric layer.

11. The method of claim 10, wherein:
the resistive metal has a second surface; and
fabricating the metal layer further comprises:
fabricating a second etch stop layer between the second surface of the resistive metal and the first dielectric layer.

12. The method of claim 11, wherein:
the first etch stop layer comprises silicon carbon nitride (SiCN); and
the second etch stop layer comprises SiCN.

13. The method of claim 11, wherein the resistive metal comprises titanium nitride (TiN).

14. The method of claim 8, wherein the metal layer comprises a second dielectric layer, wherein fabricating the metal layer further comprises:
depositing a first etch stop layer adjacent to the second dielectric layer;
depositing the resistive metal adjacent to the first etch stop layer; and
depositing a second etch stop layer adjacent to the resistive metal.

15. The method of claim 14, wherein fabricating the metal layer further comprises:
patterning the metal layer to remove excess etch stop from the first etch stop layer and excess etch stop from the second etch stop layer whereby the first etch stop layer remains adjacent to a first surface of the resistive metal and the second etch stop layer remains adjacent to a second surface of the resistive metal.

16. The method of claim 15, wherein fabricating the first dielectric layer further comprises:
etching the first dielectric layer to the second etch stop layer to begin formation of the first via.

17. The method of claim 16, wherein fabricating the first dielectric layer further comprises:
etching the second etch stop layer to expose the second surface of the resistive metal.

18. The method of claim 17, further comprising:
depositing metal into the first via.
